(19) United States
(12) Patent Application Publication
(10) Pub. No.: US 2019/0006523 A1
(43) Pub. Date: Jan. 3, 2019

(54) SEMICONDUCTOR DEVICE, AND METHOD FOR MANUFACTURING SAME

(71) Applicant: SHARP KABUSHIKI KAISHA, Sakai City, Osaka (JP)

(72) Inventor: HIROSHI NAKATSUJI, Sakai City (JP)

(73) Assignee: Sharp Kabushiki Kaisha, Sakai City,Osaka (JP)

(21) Appl. No.: 16/064,454

(22) PCT Filed: Dec. 12, 2016
(86) PCT No.: PCT/JP2016/086873

§ 371 Date: Jun. 21, 2018

(30) Foreign Application Priority Data
Dec. 21, 2015 (JP) 2015-248645

(51) Int. Cl. H01L 29/786; H01L 27/12; H01L 27/092; H01L 21/8238; H01L 29/66

(52) U.S. Cl. CPC H01L 29/78627; H01L 27/1222; H01L 27/092; H01L 29/78675; H01L 29/66757; H01L 27/1288; H01L 21/823814; H01L 29/66492; H01L 27/1274

(57) ABSTRACT

A semiconductor device (1001) includes a first thin film transistor (201) including a first semiconductor layer (3A), a gate insulating layer (5), a first gate electrode (7A) provided on the gate insulating layer (5), and first source and drain electrodes (8A), (9A), the first semiconductor layer (3A) including a first channel region (30A) and a first high-density impurity region (33sA), (33dA) containing an impurity of a first conductivity type. The first channel region (30A) includes a first channel portion (31A) and a second channel portion (32A) located between the first channel portion and the first high-density impurity region. The first channel portion (31A) contains an impurity of a second conductivity type that is different from the first conductivity type at a density higher than that in the second channel portion (32A) and the impurity of the first conductivity type at a density substantially equal to that in the second channel portion (32A).

### TECHNICAL FIELD

The present invention relates to a semiconductor device, and a method for manufacturing the same.

### BACKGROUND ART

Semiconductor devices in which a plurality of thin film transistors (hereinafter referred to as “TFTs”) are formed on a single substrate, and electronic devices including such a semiconductor device have been developed.

For example, on an active matrix substrate used for a liquid crystal display device and an organic EL display devices, TFTs (pixel TFTs) serving as switching elements are formed in respective pixels. In addition, a technique of integrally forming a driving circuit on the active matrix substrate has been proposed. The driving circuit typically has a complementary metal oxide semiconductor (CMOS) structure including p-channel type TFTs (hereinafter abbreviated to “p-type TFTs”) and n-channel type TFTs (hereinafter abbreviated to “n type TFTs”).

As these TFTs, for example, TFTs having an LDD structure (hereinafter abbreviated to “LDD structure TFTs”) may be used. In an n-type LDD structure TFT, for example, a low-density impurity region (lightly doped drain, hereinafter abbreviated to “LDD region” in some cases) containing an n-type impurity at a density lower than that in source and drain regions is provided at at least one of spaces between a channel region of the TFT and the source region and between the channel region of the TFT and the drain region. This structure allows an LDD region having a higher resistance than the source/drain region to be present between the edge of a gate electrode and the source/drain region having a low resistance, thereby achieving a significant reduction of an off-leakage current compared with a TFT without an LDD region (also referred to as a single drain structure TFT).

The LDD structure TFT being used as a TFT included in a driving circuit (driving circuit TFT), however, brings the following problems. While the driving circuit TFT is required to have a large current driving force, that is, a large on-state current, the LDD structure TFT includes the LDD region as resistance and accordingly has a smaller current driving force than single drain structure TFT. In addition, to optimize the length of the LDD region in the channel-length direction (LDD length), the circuit design may be complicated, or the size of a frame region may be increased. Furthermore, a high-speed operation driving circuit is required to have a higher reliability.

Accordingly, use of a TFT having a structure in which a part or all of the LDD region is overlapped with a gate electrode as the driving circuit TFT has been proposed (for example, PTL 1 to 3). Such a structure is referred to as a “gate overlapped LDD (GOLD) structure”. In a TFT having a GOLD structure (hereinafter abbreviated to a “GOLD structure TFT”), when a voltage is applied to the gate electrode, electrons serving as carriers are accumulated in the LDD region overlapped with the gate electrode, and accordingly, the resistance of the LDD region can be decreased. Thus, a decrease in the current driving force of the TFT can be suppressed. In addition, formation of an electric field relaxation region below the gate can achieve a higher reliability than that of an LDD structure TFT.

### Citation List

Patent Literature

PTL 1: Japanese Unexamined Patent Application Publication No. 2000-216397

PTL 2: Japanese Unexamined Patent Application Publication No, 2000-208777

PTL 3: Japanese Unexamined Patent application Publication No. 2001-085700

### SUMMARY OF INVENTION

### Technical Problem

The GOLD structure TFT, however, has a problem in that the number of photomasks used in a manufacturing process is larger than that used for the LDD structure TFT.

For example, in PTL 1 and 2, methods for manufacturing the GOLD structure TFT while suppressing as increase in the number photomasks have been proposed. However, these methods are difficult to control during the process and are not practically useful in some cases.

An embodiment of the present invention has been made in view of the above circumstance, and an object of the embodiment of the present invention is to provide a semiconductor device including a thin film transistor that can be manufactured through a process in which an increase in the number of photomasks used is suppressed and that can achieve a high reliability.

### Solution to Problem

A semiconductor device according to an embodiment of the present invention is a semiconductor device including a substrate and at least one first thin film transistor supported by the substrate. The at least one first thin film transistor includes a first semiconductor layer including a first channel region and a first high-density impurity region containing an impurity of a first conductivity type, the first high-density impurity region including a first source region and a first drain region located on an opposite side of the first source region with the first channel region interposed therebetween; a gate insulating layer formed on the first semiconductor layer; a first gate electrode provided on the gate insulating layer to overlap with the first channel region in the first semiconductor layer; a first source electrode electrically connected to the first source region; and a first drain electrode electrically connected to the first drain region. The first channel region includes a first channel portion and a second channel portion located between the first channel portion and the first high-density impurity region, the first channel portion containing an impurity of a second conductivity type that is different from the first conductivity type at a density higher than that in the second channel portion and the impurity of the first conductivity type at a density substantially equal to that in the second channel portion.

In an embodiment, the first semiconductor layer further includes a first low-density impurity region that is located between the first high-density impurity region and the first channel region and that contains the impurity of the first conductivity type at a density lower than that in the first high-density impurity region and higher than that in the first channel region. The first gate electrode is provided to overlap with the first channel region in the first semiconductor layer with the gate insulating layer interposed therebetween and not to overlap with the first low-density impurity region.

In an embodiment, the first low-density impurity region contains substantially no impurity of the second conductivity type.

In an embodiment, the semiconductor device further includes at least one second thin film transistor supported by the substrate, the at least one second thin film transistor being of the second conductivity type. The at least one second thin film transistor includes a second semiconductor layer including a second channel region and a second high-density impurity region containing the impurity of the second conductivity type that is different from the first conductivity type. The second channel portion in the first semiconductor layer contains the impurity of the second conductivity type at a density substantially equal to the density of the impurity of the second conductivity type in the second channel region in the second semiconductor layer.

In an embodiment, the first semiconductor layer and the second semiconductor layer are formed of an identical semiconductor film. The second channel portion in the first semiconductor layer and the second channel region in the second semiconductor layer contain an identical impurity element of the second conductivity type and have a substantially identical density profile of the impurity element in a thickness direction.

In an embodiment, the first channel portion and the second channel portion in the first semiconductor layer contain substantially no impurity of the first conductivity type.

In an embodiment, in the first semiconductor layer, the first channel region is adjacent to the first source region and the first drain region.

In an embodiment, the first semiconductor layer further includes another first channel region and a first-conductivity-type region that is located between the first channel region and the other first channel region and that contains the impurity of the first conductivity type. The at least one first thin film transistor further includes another first gate electrode provided to overlap with the other first channel region with the gate insulating layer interposed therebetween.

In an embodiment, the other first channel region includes another first channel portion and another second channel portion located between the other first channel portion and the first high-density impurity region and between the other first channel portion and the first-conductivity-type region. The other first channel portion contains the impurity of the second conductivity type at a density substantially equal to that in the first channel portion, and the other second channel portion contains the impurity of the second conductivity type at a density substantially equal to that in the second channel portion.

In an embodiment, the other first channel region includes another first channel portion and another second channel portion located between the other first channel portion and the first high-density impurity region, and the other second channel portion is adjacent to the first-conductivity-type region. The other first channel portion contains the impurity of the second conductivity type at a density substantially equal to that in the first channel portion, and the other second channel portion contains the impurity of the second conductivity type at a density substantially equal to that in the second channel portion.

In an embodiment, the semiconductor device further includes at least one third thin film transistor. The at least one third thin film transistor includes a third semiconductor layer including a third channel region, a third high-density impurity region containing the impurity of the first conductivity type, and a third low-density impurity region that is located between the third high-density impurity region and the third channel region and that contains the impurity of the first conductivity type at a density lower than that in the third high-density impurity region and higher than that in the third channel region, and a third gate electrode provided on the gate insulating layer to overlap with the third channel region with the gate insulating layer interposed therebetween and not to overlap with the third low-density impurity region. The third channel region contains the impurity of the second conductivity type at a density that is substantially equal to the density of the impurity of the second conductivity type in the first channel portion in the first semiconductor layer, and both ends of the third channel region are in contact with the third high-density impurity region or the third low-density impurity region.

In an embodiment, the at least one first thin film transistor includes a thin film transistor including an LDD region and a thin film transistor without an LDD region.

The first conductivity type may be n type, and the second conductivity type may be p type.

The first semiconductor layer may contain a crystalline silicon semiconductor.

A method for manufacturing a semiconductor device according to an embodiment of the present invention is a method for manufacturing a semiconductor device including at least one first thin film transistor and at least one second thin film transistor having a different conductivity type from the first thin film transistor, the method including (a) a step for forming, on a substrate, a first semiconductor layer in a form of an island to serve as an active region of the first thin film transistor and a second semiconductor layer in a form of an island to serve as an active region of the second thin film transistor; (b) a step for forming a gate insulating layer covering the first and second semiconductor layers; (c) a step for forming a first gate electrode to overlap with a region to serve as a channel region in the first semiconductor layer with the gate insulating layer interposed therebetween and forming a second gate electrode to overlap with a region to serve as a channel region in the second semiconductor layer with the gate insulating layer interposed therebetween; (d) a step for doping a region in the first semiconductor layer not covered with the first gate electrode with an impurity of a first conductivity type to form a first high-density impurity region; and (e) a step for doping a region in the second semiconductor layer not covered with the second gate electrode with an impurity of a second conductivity type to form a second high-density impurity region, further including: between the step (a) and the step (c), a channel doping step (f1) for doping a part of a region to serve as the channel region in the first semiconductor layer with the impurity of the second conductivity type to form a first channel portion in the first semiconductor layer. In the region to serve as the channel region in the first semiconductor layer, a region not doped with the impurity of the second conductivity type in the step (f1) becomes a second channel portion. The second channel portion in the first semiconductor layer contains the impurity at a density that is substantially equal to a density of the impurity in the channel region in the second semiconductor layer.

In an embodiment, the method for manufacturing a semiconductor device further includes, between the step (a) and the step (c), a step (f2) for doping the region to serve as the channel region in the second semiconductor layer and the region to serve as the channel region in the first semiconductor layer with the impurity of the second conductivity type. In the region to serve as the channel region in the first semiconductor layer, a region doped with the impurity of the second type in both the step (f1) and the step (f2) serves as the first channel portion, and a region not doped with the impurity of the second conductivity type in the step (f1) but doped with the impurity of the second conductivity type in the step (f2) becomes the second channel portion.

In an embodiment, the step (d) is a step for doping a region in the first semiconductor layer not covered with the first gate electrode with the impurity of the first conductivity type to form the first high-density impurity region and a first low-density impurity region that is located on a channel side of the first high-density impurity region and that contains the impurity of the first conductivity type at a density lower than a density is the first high-density impurity region.

### Advantageous Effects of Invention

According to an embodiment of the present invention, it is possible to provide a semiconductor device including a thin film transistor that can be manufactured through a process in which as increase in the number of photomasks used is suppressed and that can achieve a high reliability.

### BRIEF DESCRIPTION OF DRAWINGS

FIG. 1 schematically illustrates a cross-section of a first TFT (first-conductivity-type CDM-LDD structure TFT) 201 and a second TFT (second-conductivity-type TFT) 202 in a semiconductor device 1001 according to a first embodiment.

FIGS. 2(a) to 2(d) each schematically illustrate cross-sections in a process for describing an exemplary method for manufacturing the first TFT 201 and the second TFT 202 in the semiconductor device 1001 according to the first embodiment.

FIGS. 3(a) to 3(c) each schematically illustrate cross-sections in the process for describing the exemplary method for manufacturing the first TFT 201 and the second TFT 202 in the semiconductor device 1001 according to the first embodiment.

FIGS. 4(a) and 4(b) each schematically illustrate cross-sections in the process for describing the exemplary method for manufacturing the first TFT 201 and the second TFT 202 in the semiconductor device 1001 according to the first embodiment.

FIGS. 5(a) to 5(c) each schematically illustrate cross-sections in a process for describing an exemplary method for manufacturing a third TFT (first-conductivity-type CDM-type TFT) 203 and the second TFT (second-conductivity-type TFT) 202 in a semiconductor device 1002 according to a second embodiment.

FIGS. 6(a) and 6(b) each schematically illustrate cross-sections in the process for describing the exemplary method for manufacturing the third TFT 203 and the second TFT 202 in the semiconductor device 1002 according to the second embodiment.

FIGS. 7(a) and 7(b) each schematically illustrate cross-sections in the process for describing the exemplary method for manufacturing the third TFT 203 and the second TFT 202 in the semiconductor device 1002 according to the second embodiment.

FIGS. 8(a) to 8(d) each schematically illustrate cross-sections in a process for describing an exemplary method for manufacturing fourth and fifth TFTs (first-conductivity-type double-gate CDM-LDD structure TFTs) 204 and 205 and the second TFT (second-conductivity-type TFT) 202 in a semiconductor device 1003 according to a third embodiment.

FIGS. 9(a) to 9(c) each schematically Illustrate cross-sections in the process for describing the exemplary method for manufacturing the fourth TFT 204, the fifth TFT 205, and the second TFT 202 in the semiconductor device 1003 according to the third embodiment.

FIGS. 10(a) to 10(d) each schematically illustrate cross-sections in a process for describing an exemplary method for manufacturing a sixth TFT (first-conductivity-type LDD structure TFT) 206 concurrently with the first-conductivity-type CDM-type TFT (e.g., the first TFT 201) and the second TFT (second-conductivity-type TFT) 202 in a semiconductor device 1004 according to a fourth embodiment.

FIGS. 11(a) to 11(c) each schematically illustrate cross-sections in the process for describing the exemplary method for manufacturing the first TFT 201, the second TFT 202, and the sixth TFT 206 in the semiconductor device 1004 according to the fourth embodiment.

FIG. 12 illustrates a cross-section of an example of the semiconductor device 1002 according to the second embodiment.

### DESCRIPTION OF EMBODIMENTS

The present inventor has studied a novel TFT structure that can be manufactured through a simple process and that can achieve a high reliability. As a result, the present inventor has found out that a higher reliability than that of an LDD structure TFT can be achieved by forming, in a channel region of an LDD structure TFT of a first conductivity type (e.g., n type), a channel doped portion containing a second-conductivity-type (e.g., p-type) impurity for adjusting a threshold voltage and a channel doped modulated portion in which the density of the second-conductivity-type impurity is lower than that in the channel doped portion. The channel doped modulated portion is provided at, for example, spaces between the channel doped portion and a source/drain region or an LDD region. As will be described later, the channel doped modulated portion may produce the same or substantially the same effects as the LDD region covered with a gate electrode (GOLD region) in a GOLD structure TFT, although the conductivity type is different. A TFT including the channel doped modulated portion may herein be referred to as a “channel-doped-modulated-type TFT”.

A semiconductor device according to an embodiment of the present invention is based on the above knowledge and includes a first thin film transistor that is the channel-doped-modulated-type TFT (abbreviated to a “CDM-type TFT”) and a second thin film transistor having a different conductivity type from the first TFT on a single substrate. A CDM portion of the first thin film transistor is formed, for example, by using a channel doping step for the second thin film transistor. The first thin film transistor may Include an LDD region. The CDM-type TFT including an LDD region may be referred to as a channel-doped-modulated-type LDD structure TFT (abbreviated to a “CDM-LDD structure TFT”).

Note that the “semiconductor device” herein widely includes a substrate on which a functional circuit is formed, an active matrix substrate, and display devices such as a liquid crystal display device and an organic EL display device. In a case of an active matrix substrate, for example, the channel-doped-modulated-type TFT may be used as a TFT included in a driving circuit or a CMOS.

### First Embodiment

A semiconductor device according to a first embodiment will be described below with reference to some of the drawings.

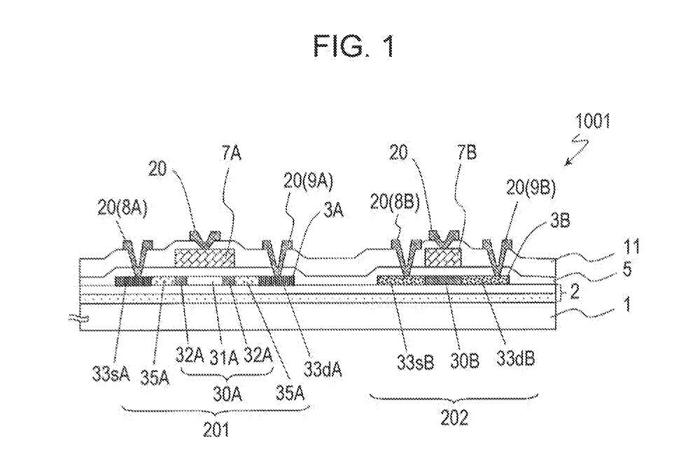

FIG. 1 is a cross-sectional view of a semiconductor device 1001 according to this embodiment.

The semiconductor device 1001 includes a substrate 1 and a first TFT 201 and a second TFT 202 that are supported by the substrate 1. Active regions of the first TFT 201 and the second TFT 202 are formed of the same semiconductor film. The first TFT 201 is a first-conductivity-type (e.g., n-type) TFT, and the second TFT 202 is a second-conductivity-type (e.g., p-type) TFT. The second conductivity type is different from the first conductivity type.

The first TFT 201 according to this embodiment is a channel-doped-modulated-type LDD structure TFT (CDM-LDD structure TFT). The structure of the second TFT 202 is not limited to a particular structure. The second TET 202 herein is a single drain structure TFT.

The same or substantially the same components of the first TFT 201 and the second TFT 202 are denoted by the same reference numerals. Note that some components of the first TFT 201 are denoted by reference numerals with “A” following a numeral, and some components of the second TFT 202 are denoted by reference numerals with “B” following a numeral.

<Structure of First TFT 201>

The first TFT 201 includes a semiconductor layer 3A formed on the substrate 1, a gate insulating layer 5 covering the semiconductor layer 3A, a gate electrode 7A formed on the gate insulating layer 5, an interlayer insulating layer 11 covering the gate electrode 7A and the semiconductor layer 3A, and an electrode/wiring 20 provided on the interlayer insulating layer 11. The electrode/wiring 20 includes a source electrode 8A and a drain electrode 9A electrically connected to the semiconductor layer 3A and wiring electrically connected to the gate electrode 7A. Also, a base insulating layer 2 may be provided between the substrate 1 and the semiconductor layer 3A.

The semiconductor layer 3A includes a channel region 30A, a source region 33sA, a drain region 33dA, and a low-density impurity region (LDD region) 35A. The source region 33sA and the drain region 33dA may be herein together referred to as a “high-density impurity region 33A”.

The high-density impurity region 33A is a first-conductivity-type region (e.g., n⁺ region) containing a first-conductivity-type impurity (e.g., n-type impurity) The LDD region 35A is a first-conductivity-type region (e.g., n⁻ region) containing the first-conductivity-type impurity at a density higher than that in the channel region 30A and lower than that in the high-density impurity region 33A. The n-type impurity may be phosphorus (P), arsenic (As), or the like. In this example, the LDD region 35A is provided between the channel region 30A and the source region 33sA and between the channel region 30A and the drain region 33dA. Note that the LDD region 35A is provided at least one of spaces between the channel region 30A and the source region 33sA and between the channel region 30A and the drain region 33dA.

The channel region 30A includes a channel-doped portion 31A and a channel-doped modulated portion 32A that is provided on each of the source side and the drain side of the CD portion 31A. The channel-doped portion (also referred to as first channel portion) 31A is herein abbreviated to a “CD portion”. In addition, the channel-doped modulated portion (also referred to as second channel portion) 32A is herein abbreviated to a “CDM portion”. The CDM portion 32A may be in contact with the LDD region 35A. The CDM portion 32A is provided on at least one of the source side and the drain side of the CD portion 31A.

The CD portion 31A is doped with a second-conductivity-type impurity (e.g., p-type impurity) (channel doping is performed) in order to control the threshold of the first TFT 201 to a predetermined value. The p-type impurity may be boron, for example. The density of the second-conductivity-type impurity in the CD portion 31A may be selected in accordance with the threshold of the first TFT 201. On the other hand, the density of the second-conductivity-type impurity in the CDM portion 32A is lower than that in the CD portion 31A. The CDM portion 32A may or may not contain the second-conductivity-type impurity. The density of the second-conductivity-type impurity in the CDM portion 32A is substantially equal to the density of the second-conductivity-type impurity in a channel region 30B of the second TFT 202. If the channel region of the second TFT 202 is doped with the second-conductivity-type impurity (channel doping is performed), the CDM portion 32A may contain the same second-conductivity-type impurity element at a density substantially equal to that in the region where channel doping is performed in the second TFT 202.

The density of the first-conductivity-type impurity in the CD portion 31A is substantially equal to the density of the first-conductivity-type impurity in the CDM portion 32A. Thus, the CDM portion 32A differs from a GOLD region. The CD portion 31A and the CDM portion 32A may contain substantially no first-conductive-type impurity. The phrase “to contain substantially no impurity” means that the impurity is not added on purpose, and an impurity may partially diffuse to the relevant region from another region in the semiconductor layer 3A.

The gate electrode 7A is provided to overlap with the channel region 30A in the semiconductor layer 3A with the gate insulating layer 5 interposed therebetween and not to overlap with the LDD region 35A and the high-density impurity region 33A. The ends of the gate electrode 7A may align with the ends of the LDD region 35A on the channel region 30A side. In addition, as illustrated in the drawing, the interfaces between the LDD region 35A and the CDM portion 32A may align with the ends of the gate electrode 7A when seen from the normal direction of the substrate 1.

The gate insulating layer 5 and the interlayer insulating layer 11 are provided with a source contact hole reaching the source region 33sA in the semiconductor layer 3A and a drain contact hole reaching the drain region 33dA in the semiconductor layer 3A. In addition, the interlayer insulating layer 11 is provided with a gate contact hole reaching the gate electrode 7A.

The source electrode 8A is provided on the interlayer insulating layer 11 and in the source contact hole, and is in contact with the source region 33sA in the source contact hole. The drain electrode 9A is provided on the interlayer insulating layer 11 and in the drain contact hole, and is in contact with the drain region 33dA in the drain contact hole. In addition, a part of the electrode/wiring 20 is provided to be in contact with the gate electrode 7A in the gate contact hole.

<Structure of Second TFT 202>

The second TFT 202 includes a semiconductor layer 3B formed on the substrate 1, the gate insulating layer 5 that extends to cover the semiconductor layer 3B, a gate electrode 7B formed on the gate insulating layer 5, the interlayer insulating layer 11 that extends to cover the gate electrode 7B and the semiconductor layer 3B, and a source electrode 8B and a drain electrode 9B electrically connected to the semiconductor layer 3B. In this example, the second TFT 202 has a single drain structure.

The semiconductor layer 3B includes the channel region 30B, a source region 33sB, and a drain region 33dB (together referred to as a “high-density impurity region 33B”). The high-density impurity region 33B is a second-conductivity-type region (e.g., p⁺ region) containing a second-conductivity-type impurity (e.g., p-type impurity) at a density higher than that in the channel region 30B. The channel region 30B may be doped with the second-conductivity-type impurity (channel doping may be performed) in order to control the threshold of the second TFT 202 to a predetermined value. In a case in which the predetermined threshold can be obtained without doping with the second-conductivity-type impurity, channel doping does not have to be performed. In this case, the channel region 30B may contain substantially no second-conductivity-type impurity. Thus, the density of the second-conductivity-type impurity in the channel region 30B may be selected in accordance with the threshold of the second TFT 202. The gate electrode 7B is provided to overlap with the channel region 30B in the semiconductor layer 3B with the gate insulating layer 5 interposed therebetween. The ends of the gate electrode 7B may align with the ends of the channel region 30B when seen from the normal direction of the substrate 1. The other structure is the same as that of the first TFT 201, and therefore a description thereof will be omitted.

In the first TFT 201 according to this embodiment, below the gate electrode 7A, the CDM portion 32A containing the second-conductivity-type impurity (p-type impurity in this example) is provided on each side of the CD portion 31A. The CDM portion 32A may have a function of decreasing the rate of hot carrier degradation by using an electric field relaxation effect produced by a density difference and a screening effect of a portion degraded by electrons induced by a gate voltage, as well as in a GOLD region in a GOLD structure TFT. Thus, it is possible to increase hot-carrier resistance, although it is not as high as that in the GOLD structure TFT. Accordingly, this embodiment can provide a highly reliable TFT that can be manufactured through a simpler process than that for the GOLD structure TFT.

In this manner, in the first TFT 201, the threshold can be adjusted by using the density of the second-conductivity-type impurity in the CD portion 31A and hot-carrier degradation resistance can be obtained in the CDM portion 32A.

In addition, the CDM portion 32A of the first TFT 201 can be formed through a step for forming the channel region of he second TFT 202. Thus, it is unnecessary to use an additional photomask for forming the CDM portion 32A, thereby manufacturing the first TFT 201 and the second TFT 202 on a single substrate without making the manufacturing process complex.

For example, as will be described later, a region to serve as the CDM portion 32A of the first TFT 201 may be doped with the second-conductivity-type impurity by using a channel doping step for the second TFT 202. In this case, the CDM portion 32A of the first TFT 201 and the channel region 30B of the second TFT 202 contain the same impurity element and have substantially the same density profile of the impurity element in the thickness direction.

The CDM portion 32A is preferably provided on each of the source side and the drain side. Thus, even in a case in which the direction of a voltage applied to the first TFT 201 changes depending on a circuit operation, the hot-carrier degradation resistance can be increased more effectively. Note that the CDM portion 32A is provided on at least either of the source side and the drain side of the CD portion 31A. For example, in a case in which the direction of a voltage applied to the first TFT 201 is constant, the CDM portion 32A may be provided only on the drain side.

The first TFT 201 may include the LDD region 35A. The LDD region 35A preferably contains substantially no second-conductivity-type impurity. Thus, as will be described later in detail, it becomes possible to suppress the resistance of the LDD region 35A to be lower than that of a conventional LDD region, thereby achieving high on-state characteristics.

The LDD region 35A herein refers to a region whose first-conductivity-type impurity density is, for example, higher than or equal to 1×10¹⁸ atom/cm³ and lower than the first-conductivity-type impurity density in the source/drain region. Thus, the LDD region 352 does not include a region containing the first-conductivity-type impurity at an extremely low density (lower than 1×10¹⁸ atoms/cm³) in the semiconductor layer. For example, although the first-conductivity-type impurity added to the LDD region 35A may partially diffuse to the channel region 30A below the gate electrode, the impurity density in the region where the impurity has diffused is considered to be extremely low, and therefore, such a region is not included in the “LDD region”.

<Method for Manufacturing Semiconductor Device 1001>

Next, an example of a method for manufacturing the first TFT 201 and the second TFT 202 will be described. In this example, description will be given by assuming that the first conductivity type is n type, the second conductivity is p type, the first TFT 201 is an n-channel type TFT, and the second TFT 202 is a p-channel type TFT. Note that the first conductivity type may be p type, and the second conductivity type may be n type.

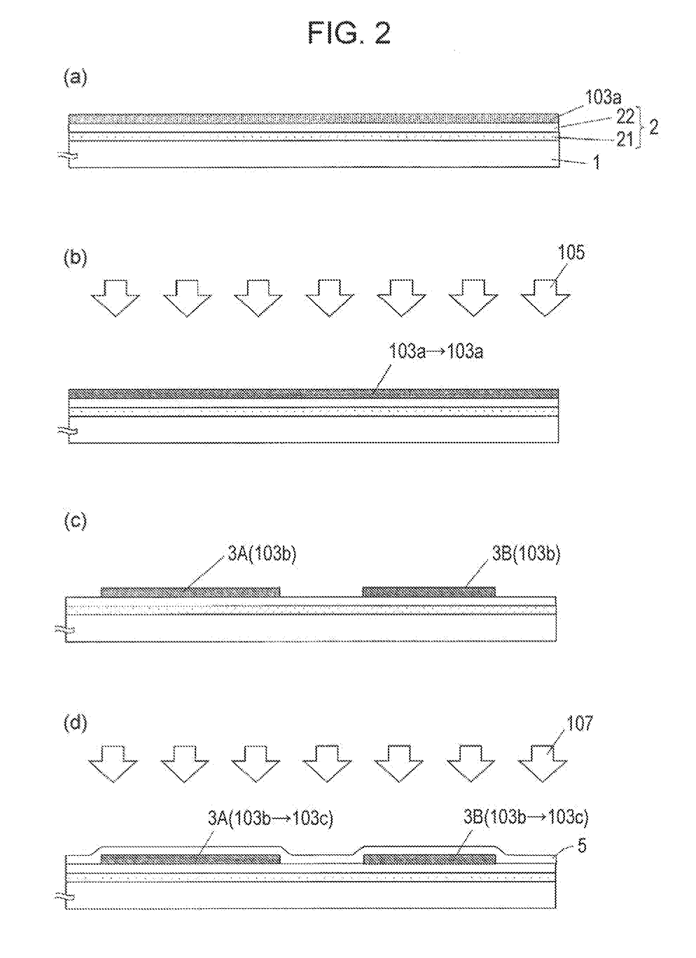

FIGS. 2 to 4 schematically illustrate cross-sections in a process performed by an exemplary method for manufacturing an LDD structure TFT 200.

First, as illustrated in FIG. 2(a), in order to prevent impurity diffusion from the substrate 1, the base insulating layer (buffer layer) 2 including a silicon oxide film, silicon nitride, a silicon oxide nitride film, and the like is formed on the substrate (e.g., glass substrate) 1 having an insulating surface. In this embodiment, for example, a silicon nitride film is formed as a first buffer layer 21 on the substrate 1, and a silicon oxide film is formed as a second buffer layer 22 thereon. Subsequently, an amorphous silicon film (a-Si film) 103a is formed on the second buffer layer 22. The a-Si film 103a may be of n type. The a-Si film 103a has a thickness of, for example, greater than or equal to 25 nm and less than or equal to 80 nm. The buffer layers 21 and 22 and the a-Si film 103a may be formed by, for example, a plasma CVD method.

Subsequently, as illustrated in FIG. 2(b), the a-Si film 103a is crystalized to obtain a crystalline silicon film (p-Si) 103b. The method for crystallization is not limited to a particular method, and any known method can be used. In this example, the a-Si film 103a is irradiated with a laser beam 105 from above the substrate 1. As the laser beam 105, for example, a XeCl excimer laser beam at a wavelength of 308 nm. may be used. Besides, a laser beam such as a XeF excimer laser beam at a wavelength of 351 nm or a KrF excimer laser beam at a wavelength of 248 nm, or a solid laser beam may be used. The entire surface of the substrate 1 may be scanned and irradiated with the laser beam 105 having a long shape.

Note that a natural oxide film on the surface of the a-Si film 103a is preferably removed before irradiation with the laser beam 105. Thus, the surface roughness of the p-Si film 103b can be reduced. In addition, in order to reduce the surface roughness of the p-Si film. 103b, the irradiation with the laser beam 105 is preferably performed in an inert atmosphere such as a nitrogen atmosphere.

Subsequently, as illustrated in FIG. 2(c), the p-Si film 103b is patterned to form the semiconductor layers 3A and 3B in the form of islands to serve as the active regions of the first TFT and the second TFT, respectively.

Subsequently, as illustrated in FIG. 2(d), the gate insulating layer 5 is formed to cover the semiconductor layers 3A and 3B. In this example, as the gate insulating layer 5, for example, a silicon oxide film having a thickness of 20 to 150 nm is used.

Subsequently, the semiconductor layer 3B may be doped with a second-conductivity-type impurity (p-type impurity in this example) 107 from above the gate insulating layer 5 to perform channel doping for adjusting the threshold voltage of the second TFT (p-channel type TFT in this example) to an appropriate value, and the semiconductor layer 3A may also be doped with the p-type impurity 107. Thus, a p-Si region 103c in which the density of the p-type impurity is adjusted is obtained. The p-type impurity may be boron, for example. The density of the p-type impurity in the p-Si region 103c may be suitably selected such that the second TFT has a desired threshold (e.g., higher than or equal to 1×10¹⁷ and lower than or equal to 1×10¹⁸). Note that the p-type impurity doping step may be skipped if as appropriate threshold can be obtained without the p-type impurity doping.

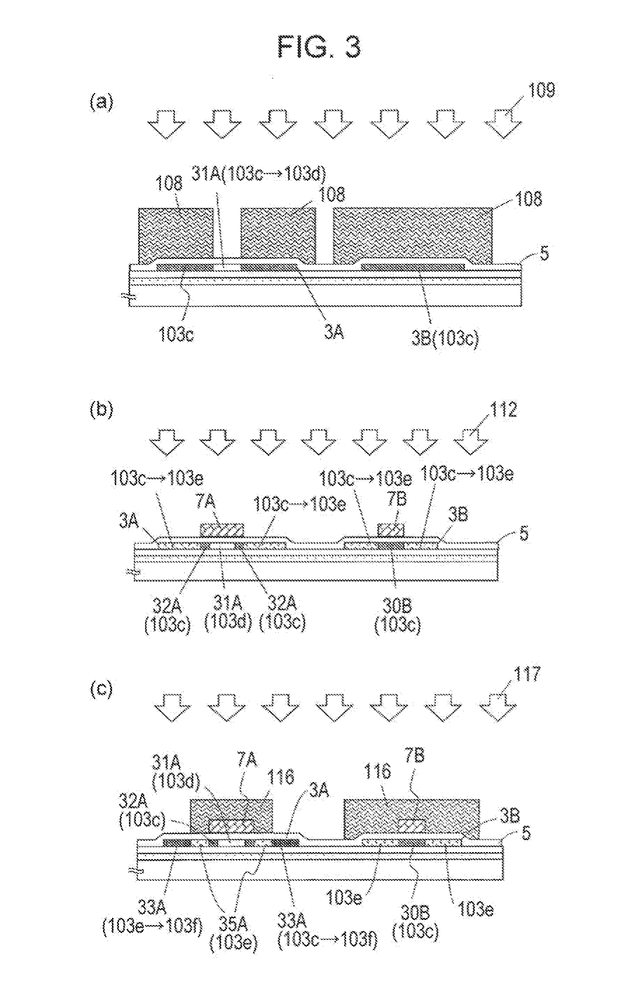

Subsequently, channel doping is performed to adjust the threshold voltage of the first TFT (n-channel type TFT in this example) to an appropriate value. Specifically, as illustrated in FIG. 3(a), a resist layer 108 is formed on the semiconductor layers 3A and 3B. The resist layer 108 has an opening on a part of a region to serve as the channel region in the semiconductor layer 3A. Subsequently, by using the resist layer 108 as a mask, the part of the semiconductor layer 3A may further be doped with a second-conductivity-type impurity (p-type impurity in this example, boron for example) 109. The other region in the semiconductor layer 3A and the semiconductor layer 3B does not have to be doped with the p-type impurity 109. Thus, a p-Si region 103d further doped with the p-type impurity 109 is formed in the semiconductor layer 3A. This region serves as the CD portion 31A of the first TFT. The density of the p-type impurity in the CD portion 31A may be suitably selected such that the first TFT has a desired threshold (e.g., higher than or equal to 1×10¹⁷ and lower than or equal to 1×10¹⁸). Subsequently, the resist layer 108 is removed.

Note that the channel doping for adjusting the threshold voltages of the second TFT and the first TFT (FIGS. 2(d) and 3(a)) may be performed before a step for forming the gate insulating layer 5. Also, the channel doping for adjusting the threshold voltage of the second TFT (FIG. 2(d)) may be performed after the channel doping for adjusting the threshold voltage of the first TFT (FIG. 3(a)). Such change in the order of steps as in this embodiment may be made also in manufacturing methods in the following embodiments.

Subsequently, as illustrated in FIG. 3(b), the gate electrodes 7A and 7B of the first TFT and the second TFT are formed on the gate insulating layer 5. The gate electrodes 7A and 7B are formed by forming a conductive film for forming gate electrodes by a sputtering method, a CVD method, or the like and by patterning the conductive film. As the conductive film for forming gate electrodes, for example, a film containing W, Ta, Ti, Mo, or an alloy material thereof (thickness: 300 to 600 nm for example) may be used.

The gate electrode 7A is provided to cover the CD portion 31A in the semiconductor layer 3A and a part of the p-Si region 103c (portion adjacent to the CD portion 31A) with the gate insulating layer 5 interposed therebetween. In this example, the gate electrode 7A is provided to cover the entire CD portion 31A and parts of the region 103c located on the source side and the drain side of the CD portion 31A. The gate electrode 7B is provided to cover a part of the semiconductor layer 3B with the gate insulating layer 5 interposed therebetween.

Subsequently, by using the gate electrodes 7A and 7B as masks, the semiconductor layers 3A and 3B are doped with a first-conductivity-type impurity (n-type impurity in this example) 112. The n-type impurity may be phosphorus, for example. Thus, an n⁻ region 103e is formed in the semiconductor layer 3A and the semiconductor layer 3B.

In a portion of the semiconductor layer 3A covered with the gate electrode 7A, a region not doped with the n-type impurity 112 serves as the CDM portion 32A. The p-type impurity density in the CDM portion 32A is lower than the p-type impurity density in the CD portion 31A. Although the CDM portion 32A is formed on both of the source side and the drain side of the CD portion 31A in this example, the CDM portion 32A may be formed only on either side. The length of the CD portion 31A in the channel-length direction may be, for example, greater than or equal to 4 μm and less than or equal to 7 μm, and the length of the CDM portion 32A in the channel-length direction may be, for example, greater than or equal to 0.5 μm and less than or equal to 3.0 μm.

In a portion of the semiconductor layer 3B covered with the gate electrode 7B, a region not doped with the n-type impurity 112 serves as the channel region 30B of the second TFT. The CDM portion 32A and the channel region 30B are each the p-Si region 103c doped with the p-type impurity 107 in the step illustrated in FIG. 2(d).

Subsequently, as illustrated in FIG. 3(c), a resist layer 116 is formed on the semiconductor layers 3A and 3B. The resist layer 116 has openings on parts of a region to serve as a high-density impurity region in the n⁻ region 103e in the semiconductor layer 3A. Subsequently, by using the resist layer 116 as a mask, the semiconductor layer 3A is doped with a first-conductivity-type impurity (n-type impurity in this example, phosphorus for example) 117. Thus, an n⁺ region 103f to serve as the high-density impurity region 33A is formed in the semiconductor layer 3A.

In the n⁻ region 103e, a region not doped with the n-type impurity 117 serves as the LDD region 35A. The density of the n-type impurity in the LDD region 35A is lower than the density of the n-type impurity in the high-density impurity region 33A. Thus, the semiconductor layer 3A to serve as the active region of the first TFT is obtained. Subsequently, the resist layer 116 is removed.

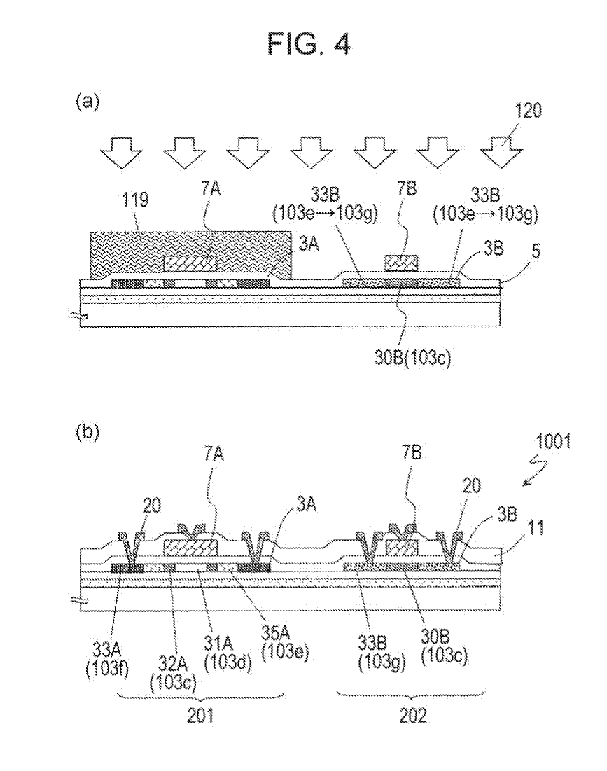

Subsequently, as illustrated in FIG. 4(a), a resist layer 119 is formed to cover the semiconductor layer 3A. Subsequently, by using the resist layer 119 and the gate electrode 7B as masks, the semiconductor layer 3B is doped with a second-conductivity-type impurity (p-type impurity in this example, boron for example) 120. Thus, a p⁺ region 103g to serve as the high-density impurity region 33B is formed in the semiconductor layer 3B. Thus, the semiconductor layer 3B to serve as the active region of the second TFT is obtained. Subsequently, the resist layer 119 is removed.

Subsequently, as illustrated in FIG. 4(b), the interlayer insulating layer 11 is formed to cover the semiconductor layers 3A and 3B. As the interlayer insulating layer 11, a silicon nitride film and a silicon oxide film may be formed in this order. Subsequently, source contact holes and drain contact holes are formed in the gate insulating layer 5 and the interlayer insulating layer 11, and gate contact holes reaching the gate electrodes 7A and 7B are formed in the interlayer insulating layer 11.

Subsequently, a film formed of a metal material is formed on the interlayer insulating layer 11 and in these contact holes and is patterned to obtain the electrode/wiring 20. Thus, the first TFT 201 and the second TFT 202 are manufactured. Subsequently, a protective film may be formed on the first TFT 201 and the second TFT 202 as needed.

With the above method, it is possible to fabricate an n-type CDM-LDD structure TFT having a higher reliability than an LDD structure TFT without increasing the number of photomasks compared with a conventional process for fabricating an n-type LDD structure TFT and a p-type TFT on a single substrate. Accordingly, this embodiment may be suitably applied to a CMOS circuit including an n-channel type TFT and a p-channel type TFT in a complementary manner, for example.

In a conventional process disclosed in PTL 3 or the like, since the number of photomasks is decreased, the entire semiconductor layer of an n-type TFT is doped with the p-type impurity for adjusting the threshold. Thus, a region to serve as the LDD region of the n-type TFT is doped with the p-type impurity at the same density as that in the channel region. In contrast, in the above method, the LDD region 35A of the first TFT 201 is not doped with the p-type impurity for adjusting the threshold of the first TFT 201. Accordingly, in a case of doping with the n-type impurity for forming the LDD region at the same density, the sheet resistance of the LDD region 35A of the first TFT 201 is lower than the sheet resistance of the LDD region of the above-described conventional LDD structure TFT. Therefore, the first TFT 201 can have a larger on-state current than the conventional LDD structure TFT.

In addition, by using the above method, the CDM portion 32A can be formed below the gate electrode 7A of the first TFT 201 without using an additional photomask. Accordingly, the amount of hot carrier degradation can be suppressed compared with the conventional LDD structure TFT without a CDM portion, thereby increasing the reliability. Thus, at the time of designing while estimating current characteristics of a degraded TFT, current in the worst case can be larger than before, thereby achieving miniaturization of the TFT. Therefore, this embodiment is useful in narrowing the frame of an active matrix substrate when being applied to a peripheral circuit of the active matrix substrate. In addition, since the reliability can be increased, a high voltage driving circuit can also be designed.

### Second Embodiment

A semiconductor device according to a second embodiment of the present invention will be described below with reference to some of the drawings.

The semiconductor device according to this embodiment differs from that in the above-described embodiment in that a TFT without an LDD region is used as a first-conductivity-type channel modulated type TFT (CDM-type TFT). Note that the semiconductor device according to this embodiment may further include another TFT such as a CDM-LDD structure TFT. Now, an exemplary case in which the first conductivity type is n type and the second conductivity type is p type will be described.

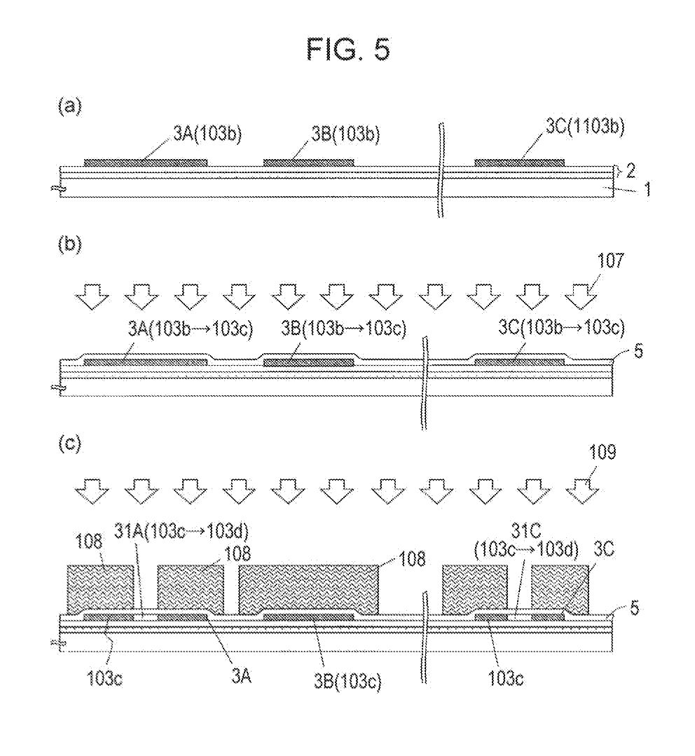

FIGS. 5 to 7 illustrate cross-sections in a process for describing an exemplary method for manufacturing a semiconductor device 1002 according to this embodiment. In these figures, the same or substantially the same components as those in FIGS. 2 to 4 are denoted by the same reference numerals. The semiconductor device 1002 includes at least a first-conductivity-type CDM-type TFT (a third TFT 203) and a second-conductivity-type TFT (the second TFT 202). Now, an example in which the semiconductor device 1002 further includes a CDM-LDD structure TFT (the first TFT 201) will be described. Note that the method for manufacturing the first TFT 201 and the second TFT 202 is the same or substantially the same as the method described above with reference to FIGS. 2 to 4, and therefore a description thereof will be omitted as appropriate.

First, by the same or substantially the same method as the method described above with reference to FIGS. 2(a) and 2(b), the p-Si film 103b is formed on the substrate 1. Subsequently, as illustrated in FIG. 5(a), the p-Si film 103b is patterned to form the semiconductor layers 3A and 3B and a semiconductor layer 3C in the form of islands to serve as active regions of the first TFT, the second TFT, and the second TFT, respectively.

Subsequently, as illustrated in FIG. 5(b), the gate insulating layer 5 is formed to cover the semiconductor layers 3A, 3B, and 3C. Subsequently, channel doping is performed to adjust the threshold voltage of the second TFT (p-channel type TFT in this example) to an appropriate value. Specifically, the semiconductor layers 3A, 3B, and 3C are doped with the second-conductivity-type impurity (p-type impurity in this example) 107 from above the gate insulating layer 5 to obtain the p-Si region 103c in which the density of the p-type impurity is adjusted.

Subsequently, as illustrated in FIG. 5(c), channel doping is performed to adjust the threshold voltages of the first TFT and the third TFT to appropriate values. Specifically, the resist layer 108 is formed on the semiconductor layers 3A, 3B, and 3C. The resist layer 108 has openings on parts of regions to serve as channel regions in the semiconductor layers 3A and 3C. Subsequently, by using the resist layer 108 as a mask, the parts of the semiconductor layers 3A and 3C are further doped with the second-conductivity-type impurity (p-type impurity in this example, boron for example) 109. Thus, the p-Si region 103d further doped with the p-type impurity 109 is formed in the semiconductor layers 3A and 3C. The p-Si region 103d in the semiconductor layer 3C serves as a CD portion 31C of the third TFT. Subsequently, the resist layer 108 is removed.

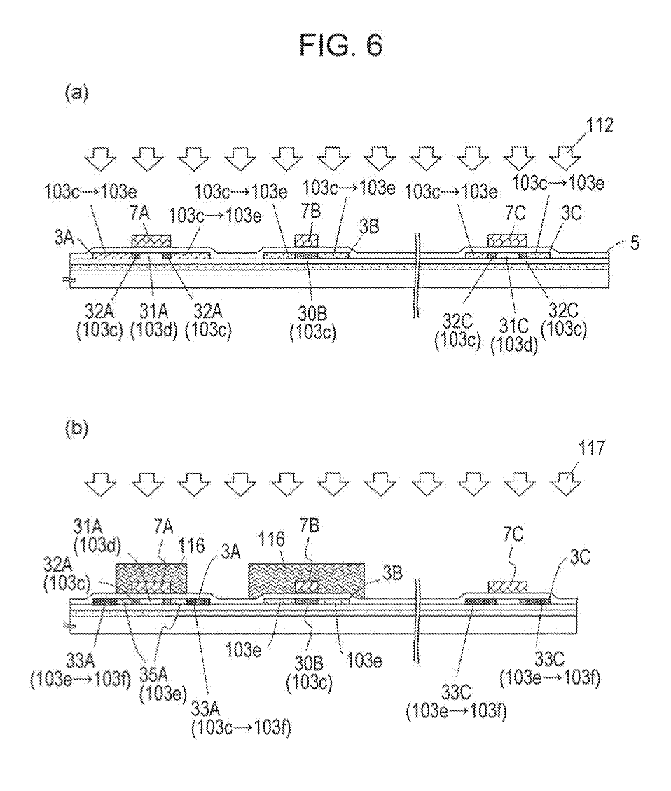

Subsequently, as illustrated in FIG. 6(a), the gate electrodes 7A and 7B and a gate electrode 7C of the first TFT, the second TFT, and the third TFT are formed on the gate insulating layer 5. The gate electrode 7C is provided to cover the CD portion 31C in the semiconductor layer 3C and parts of the p-Si region 103c (portions adjacent to the CD portion 31C) with the gate insulating layer 5 interposed therebetween. In this example, the gate electrode 7C is provided to cover the entire CD portion 31C and parts of the region 103c located on the source side and the drain side of the CD portion 31C.

Subsequently, by using the gate electrodes 7A, 7B, and 7C as masks, the semiconductor layers 3A, 3B, and 3C are doped with the first-conductivity-type impurity (n-type impurity in this example) 112. Thus, the n⁻ region 103e is formed in the semiconductor layers 3A, 3B, and 3C.

In a portion of the semiconductor layer 3C covered with the gate electrode 7C, a region not doped with the n-type impurity 112 serves as a CDM portion 32C. The p-type impurity density in the CDM portion 32C (the p-Si region 103c) is lower than the p-type impurity density in the CD portion 31C (the p-Si region 103d). Although the CDM portion 32C is formed on both of the source side and the drain side of the CD portion 31C in this example, the CDM portion 32C may be formed only on either side. Appropriate ranges of the lengths of the CD portion 31C and the CDM portion 32C in the channel-length direction may be the same as the appropriate ranges of the lengths of the CD portion 31A and the CDM portion 32A in the channel-length direction, respectively.

Subsequently, as illustrated in FIG. 6(b), the resist layer 116 is formed on the semiconductor layers 3A and 3B. The resist layer 116 has openings on parts of a region to serve as a high-density impurity region in the semiconductor layer 3A. Subsequently, by using the resist layer 116 and the gate electrode 70 as masks, the semiconductor layers 3A and 3C are doped with the first-conductivity-type impurity (n-type impurity in this example, phosphorus for example) 117. Thus, the n⁺ region 103f is formed in the semiconductor layers 3A and 3C. The n⁺ region 103f in the semiconductor layer 3C serves as a source/drain region (high-density impurity region) 33C. Since the semiconductor layer 3C does not include an LDD region, the high-density impurity region 33C is provided to be adjacent to the channel region (including the CD portion 31C and the CDM portion 32C).

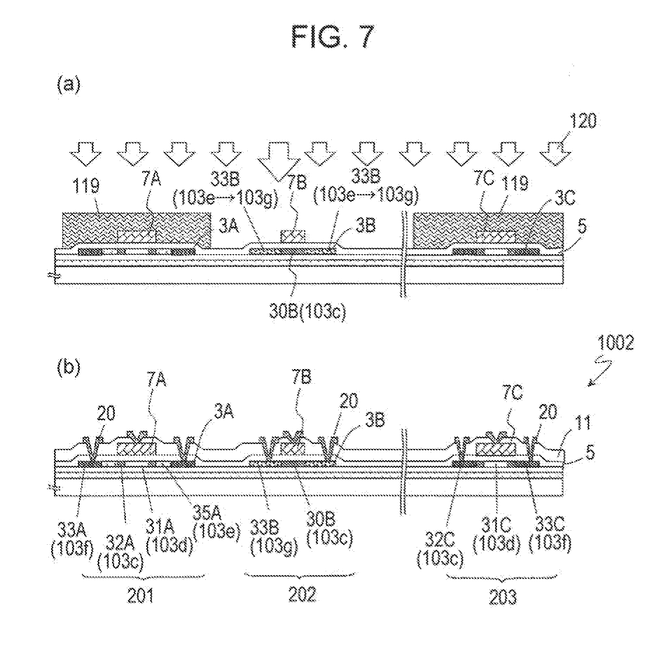

Subsequently, as illustrated in FIG. 7(a), the resist layer 119 is provided to cover the semiconductor layers 3A and 3C, and then the p⁺ region 103g to serve as the high-density impurity region 33B is formed in the semiconductor layer 3B by the method described above with reference to FIG. 4(a).

Subsequently, as illustrated in FIG. 7(b), the interlayer insulating layer 11 is formed to cover the semiconductor layers 3A, 3B, and 3C. Subsequently, as described above with reference to FIG. 4(b), contact holes are formed in the gate insulating layer 5 and the interlayer insulating layer 11, and then the electrode/wiring 20 is formed. Thus, the semiconductor device 1002 including the first TFT 201, the second TFT 202, and the third TFT 203 is manufactured.

Since the semiconductor device 1002 according to this embodiment includes the third TFT 203, which is a first-conductivity-type CDM-type TFT, and the second TFT 202, which is a second-conductivity-type TFT, the same or substantially the same effects as those in the above-described embodiment can be obtained.

As illustrated in FIG. 7(b), the semiconductor device 1002 may further include the first TFT 201 having an LDD structure. The first TFT 201 having an LDD structure may be suitably applied to a circuit that operates at a high voltage, such as a gate driver. On the other hand, the third TFT 203 without an LDD structure may be applied to a circuit that operates at a low voltage, such as an SSD. Not having an LDD structure, the third TFT 203 is advantageous in that the element area can be made smaller than that of the first TFT 201. In this manner, according to this embodiment, it is possible to use the first-conductivity-type TFTs of two types according to a circuit to be applied to. By using a CDM-type TFT (the third TFT 203) without an LDD structure as one of a plurality of n-type TFTs included in the semiconductor device, the circuit area can be reduced. In addition, in the above method, the third TFT 203 can be fabricated without increasing the number of photomasks through the same process as that of the first TFT 201 and the second TFT 202. Accordingly, it is possible to concurrently form a circuit that operates at a low voltage and a circuit that operates at a high voltage on a single substrate.

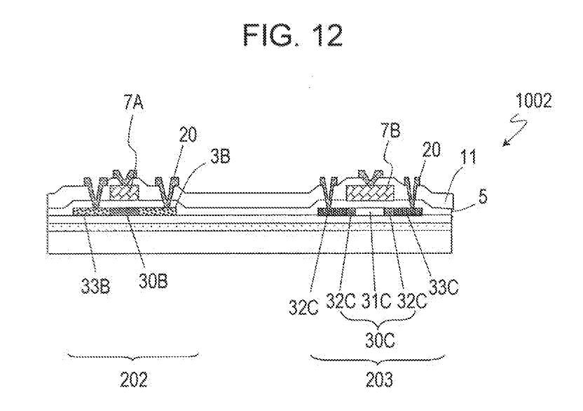

In a case in which this embodiment is applied to, for example, a semiconductor device including only a circuit that operates at a low voltage (e.g., memory liquid crystal display), as illustrated in FIG. 12, only the third TFT 203 without an LDD structure may be manufactured as a CDM-type TFT. In this case, in the step illustrated in FIG. 6(b), doping with the n-type impurity may be performed by using the gate electrodes 7B and 7C as masks without forming the resist layer 116. Thus, the number of photomasks can be further decreased.

### Third Embodiment

A semiconductor device according to a third embodiment of the present invention will be described below with reference to some of the drawings.

The semiconductor device according to this embodiment differs from those in the above-described embodiments in that a TFT having a multi-gate structure (multi-gate-CDM-type TFT) is used as a first-conductivity-type CDM-type TFT. The semiconductor device according to this embodiment may further include another CDM-type TFT having a single gate structure.

In the multi-gate-CDM-type TFT, two or more gate electrodes are provided in series to a single semiconductor layer. Thus, a voltage applied between a source and a drain can be dispersed, the off-leakage current can be effectively suppressed, and a decrease in reliability due to hot carriers can be suppressed. In the multi-gate structure, a plurality of channel regions are formed for a single semiconductor layer. For example, two channel regions may be formed for a semiconductor layer by providing two gate electrodes in series so as to overlap with the semiconductor layer (dual-gate structure). Each of the plurality of channel regions may include a CD portion and a CDM portion. The multi-gate-CDM-type TFT may have an LDD structure.

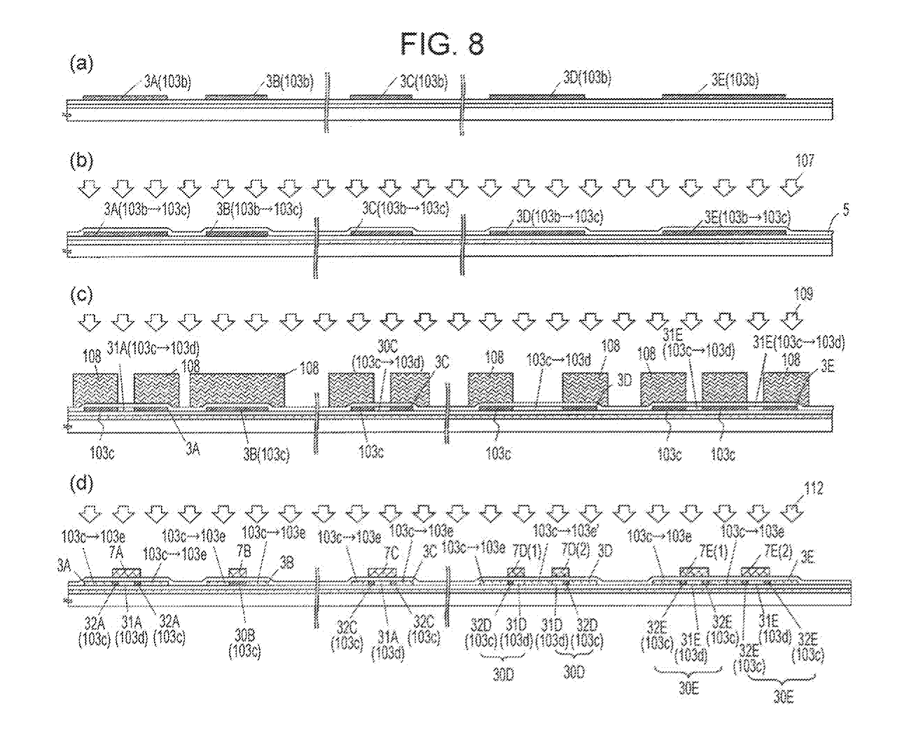

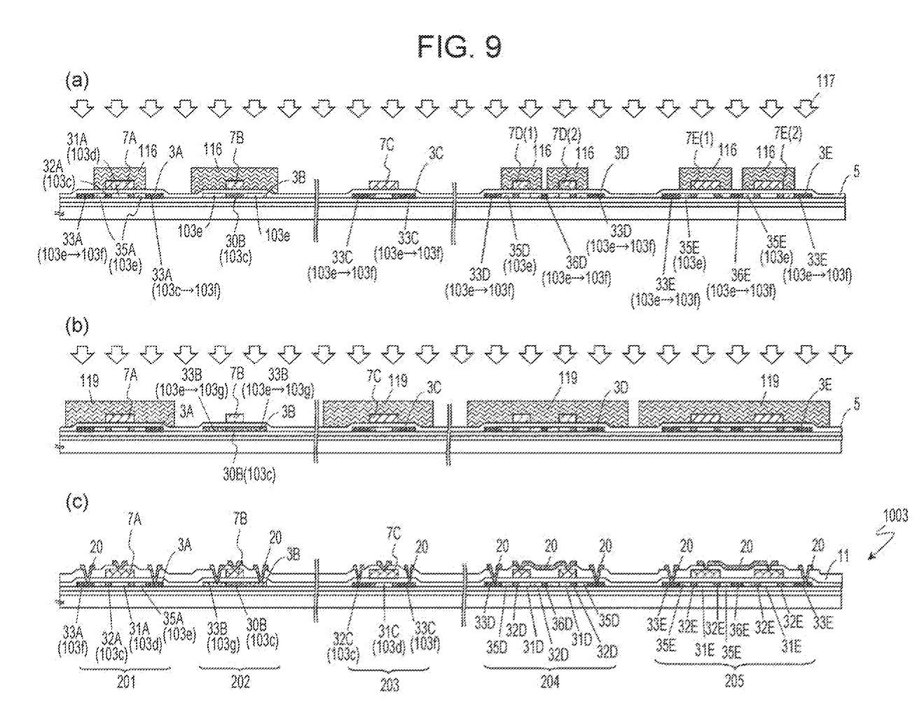

FIGS. 8 and 9 illustrate cross-sections in a process for describing an exemplary method for manufacturing a semiconductor device 1003 according to this embodiment. In these figures, the same or substantially the same components as those in FIGS. 2 to 7 are denoted by the same reference numerals.

In this embodiment, an example in which the first TFT 201, the second TFT 202, and the third TFT 203 described above and first-conductivity-type multi-gate-CDM-type TFTs (a fourth TFT 204 and a fifth TFT 205) are formed on a single substrate will be described. Note that the semiconductor device 1003 includes at least a first-conductivity-type multi-gate-CDM-type TFT (the fourth TFT 204 or the fifth TFT 205) and a second-conductivity-type TFT (the second TFT 202). In the fourth TFT 204, the CDM portion is provided only on one side of the CD portion in each channel region. In the fifth TFT 205, the CDM portion is provided on both sides of the CD portion in each channel region. Although the fourth and fifth TFTs 204 and 205 are each a dual-gate-CDM-type TFT including an LDD structure, the multi-gate-CDM-type TFT according to this embodiment does not have to include an LDD structure or may include three or more gate electrodes.

Now, an exemplary case in which the first conductivity type is n type and the second conductivity type is p type will be described. The method for manufacturing the first TFT 201, the second TFT 202, and the third TFT 203 is the same or substantially the same as any of the methods described above with reference to FIGS. 2 to 7, and therefore a description thereof will be omitted as appropriate.

First, by the same or substantially the same method as the method described above with reference to FIGS. 2(a) and 2(b), the p-Si film 103b is formed on the substrate 1. Subsequently, as illustrated in FIG. 8(a), the p-Si film 103b is patterned to form the semiconductor layers 3A to 3C and semiconductor layers 3D and 3E in the form of islands to serve as active regions of the first to fifth TFTs, respectively.

Subsequently, as illustrated in FIG. 8(b), the gate insulating layer 5 is formed to cover the semiconductor layers 3A to 3E. Subsequently, channel doping is performed to adjust the threshold voltage of the second TFT to an appropriate value. Specifically, the semiconductor layers 3A to 3E are doped with the p-type impurity 107 from above the gate insulating layer 5 to obtain the p-Si region 103c in which the density of the p-type impurity is adjusted.

Subsequently, as illustrated in FIG. 8(c), channel doping is performed to adjust the threshold voltages of the first TFT and the third TFT to appropriate values. Specifically, the resist layer 108 is formed on the semiconductor layers 3A to 3E. The resist layer 108 has openings on parts of regions to serve as the channel regions in the semiconductor layers 3A, 3C, 3D, and 3E. In this example, an opening is formed on a portion including two regions to serve as channel regions in the semiconductor layer 3D, and two openings are formed on the respective regions to serve as channel regions in the semiconductor layer 3E.

Subsequently, by using the resist layer 108 as a mask, the semiconductor layers 3A, 3C, 3D, and 3E are further doped with the second-conductivity-type impurity (p-type impurity in this example, boron for example) 109. Thus, the p-Si region 103d further doped with the p-type impurity 109 is formed in the semiconductor layers 3A, 3C, 3D, and 3E. The p-Si region 103d in the semiconductor layer 3D includes regions to serve as CD portions of the fourth TFT. Two p-Si regions 103d in the semiconductor layer 3E serve as CD portions 31E(1) and 31E(2) of the fifth TFT. Subsequently, the resist layer 108 is removed.

Subsequently, as illustrated in FIG. 8(d), gate electrodes of the first to fifth TFTs are formed on the gate insulating layer 5. In a region in which the fourth TFT is formed, a gate electrode 7D(1) covering a part of the region 103d in the semiconductor layer 3D and a part of the p-Si region 103c adjacent to the source side of the p-Si region 103d with the gate insulating layer 5 interposed therebetween, and a gate electrode 7D(2) covering a part of the p-Si region 103d in the semiconductor layer 3D and a part of the p-Si region 103c adjacent to the drain side of the p-Si region 103d are provided with the gate insulating layer 5 interposed therebetween. The gate electrode 7D(1) and the gate electrode 7D(2) are provided with a gap interposed therebetween. The p-Si region 103d below the gate electrodes 7D(1) and 7D(2) serves as CD portions 31D. In a region in which the fifth TFT is formed, gate electrodes 75(1) and 75(2) are provided to cover the CD portions 31E in the semiconductor layer 3E and portions adjacent to the both sides of the CD portions 31E. The gate electrode 75(1) and the gate electrode 75(2) are provided with a gap interposed therebetween.

Subsequently, by using the gate electrodes 7A to 7E as masks, the semiconductor layers 3A to 3E are doped with the first-conductivity-type impurity (n-type impurity in this example) 112. Thus, the n⁻ region 103e is formed in the semiconductor layers 3A to 3E. Note that in this example, an n⁻ region 103e′ located between the two CD portions 31D in the semiconductor layer 3D contains the p-type impurity at a higher density than the other n⁻ region 103e for the p-type impurity 109 added in FIG. 8(c).

In the p-Si region 103c in the semiconductor layer 3D, a region that is covered with the gate electrode 7D and is not doped with the n-type impurity 112 serves as a CDM portion 32D. Thus, channel regions 30D each including the corresponding CD portion 31D and the CDM portion 32D are obtained. In the semiconductor layer 3D, since no CDM portion is formed between the two CD portions 31D, each of the CD portions 31D is adjacent to the n⁻ region 103e′ (first-conductivity-type region later). Similarly, in the p-Si region 103c in the semiconductor layer 3E, a region that is not doped with the n-type impurity 112 serves as a CDM portion 32E. Thus, channel regions 30E each including the corresponding CD portion 31E and the CDM portion 32E are obtained.

The density of the p-type impurity in each of the CDM portions 32D and 32E (the p-Si region 103c) is lower than the density of the p-type impurity in each of the CD portions 31D and 31E (the p-Si region 103d). Appropriate ranges of the lengths of each of the CD portions and the CDM portions in the channel-length direction may be the same as the appropriate ranges of the lengths of the CD portion 31A and the CDM portion 32A in the channel-length direction, respectively.

Subsequently, as illustrated in FIG. 9(a), the resist layer 116 is formed on the semiconductor layers 3A, 3B, 3D, and 3E. The resist layer 116 has openings on parts of regions to serve as high-density impurity regions in the semiconductor layers 3A, 3B, 3D, and 3E. Subsequently, by using the resist layer 116 and the gate electrode 7C as masks, the semiconductor layers 3A, 3B, 3D, and 3E are doped with the first-conductivity-type impurity (n-type impurity in this example, phosphorus for example) 117. Thus, the n⁺ region 103f is formed. The n⁺ region 103f in the semiconductor layer 3D includes high-density impurity regions 33D and 36D. The high-density impurity region 36D is located between the two CD portions 31D, that is, between the two gate electrodes 7D(1) and 7D(2) (intra-gate portion). The n⁺ region 103f in the semiconductor layer 3E includes high-density impurity regions 33E and 36E. The high-density impurity region 36E is located between the two CD portions 31E (intra-gate portion). In the n⁻ region 103e in the semiconductor layers 3D and 3E, regions not doped with the n-type impurity 117 serve as LDD regions 35D and 35E. In the semiconductor layer 3D, the LDD region 35D is formed between one of the channel regions 30D and the high-density impurity region 33D and between the other of the channel regions 30D and the high-density impurity region 36D. Similarly, in the semiconductor layer 3E, the LDD region 35E is formed between one of the channel regions 30E and the high-density impurity region 33E and between the other of the channel regions 30E and the high-density impurity region 36E.

Subsequently, as illustrated in FIG. 9(b), the resist layer 119 is formed to cover the semiconductor layers 3A, 3C, 3D, and 3E, and then the region 103a to serve as the high-density impurity region 33B is formed in the semiconductor layer 3B by the method described above with reference to FIG. 4(a).

Subsequently, as illustrated in FIG. 9(c), the interlayer insulating layer 11 is formed to cover the semiconductor layers 3A to 3E. Subsequently, as described above with reference to FIG. 4(b), contact holes are formed in the gate insulating layer 5 and the interlayer insulating layer 11, and then the electrode/wiring 20 is formed. At this time, the gate electrode 7D(1) and the gate electrode 7D(2) are electrically connected to each other via a part of the electrode/wiring 20. Similarly, the gate electrode 7E(1) and the gate electrode 7E(2) are electrically connected to each other via another part of the electrode/wiring 20. Thus, the semiconductor device 1003 is obtained.

Although the semiconductor layers 3D and 3E of the fourth TFT 204 and the fifth TFT 205 include the high-density impurity regions 36D and 36E in the intra-gate portions in the above example, openings do not have to be formed in the resist layer 116 (FIG. 9(a)) at the intra-gate portions, and the high-density impurity regions do not have to be formed in the intra-gate portions. In this case, only the LDD region is present between the two channel regions. In this canner, in the semiconductor layers 3D and 3E, the first-conductivity-type region containing the first-conductivity-type impurity between the two channel regions may be only the LDD region or may be formed of the LDD region and the high-density impurity region.

The fourth TFT 204 and the fifth TFT 205 may be suitably used for, for example, a circuit that operates at a high voltage, such as a gate driver. The semiconductor device 1003 may include both or either of the TFTs 204 and 205. Considering alignment or the like, a small width of each gate electrode (width in the channel-length direction) of a multi-gate-CDM-type TFT may cause difficulty in providing two CDM portions below each gate electrode. In such case, as in the fourth TFT 204, only a single CDM portion may be provided below each gate electrode, and no CDM portion may be provided in the intra-gate portion. On the other hand, in a circuit that operates at a higher voltage, as in the fifth TFT 205, the width of each gate electrode may be sufficiently increased, and the CDM portion may be provided below each gate electrode on both sides of a CD portion.

With the above-described method, the first-conductivity-type multi-gate-CDM-type TFT and the second-conductivity-type TFT can be fabricated through the same process without increasing the number of photomasks. In the multi-gate-CDM-type TFT, even if the width of the gate is small, by providing a CDM portion only on a side of the CD portion, a higher reliability than that of a conventional multi-gate-CDM-type TFT can be obtained.

### Fourth Embodiment

A semiconductor device according to a fourth embodiment of the present invention will be described below with reference to some of the drawings.

The semiconductor device according to this embodiment includes, in addition to the first-conductivity-type CDM-type TFT and the second-conductivity-type TFT, a first-conductivity-type LDD structure TFT without a CDM portion on the same substrate.

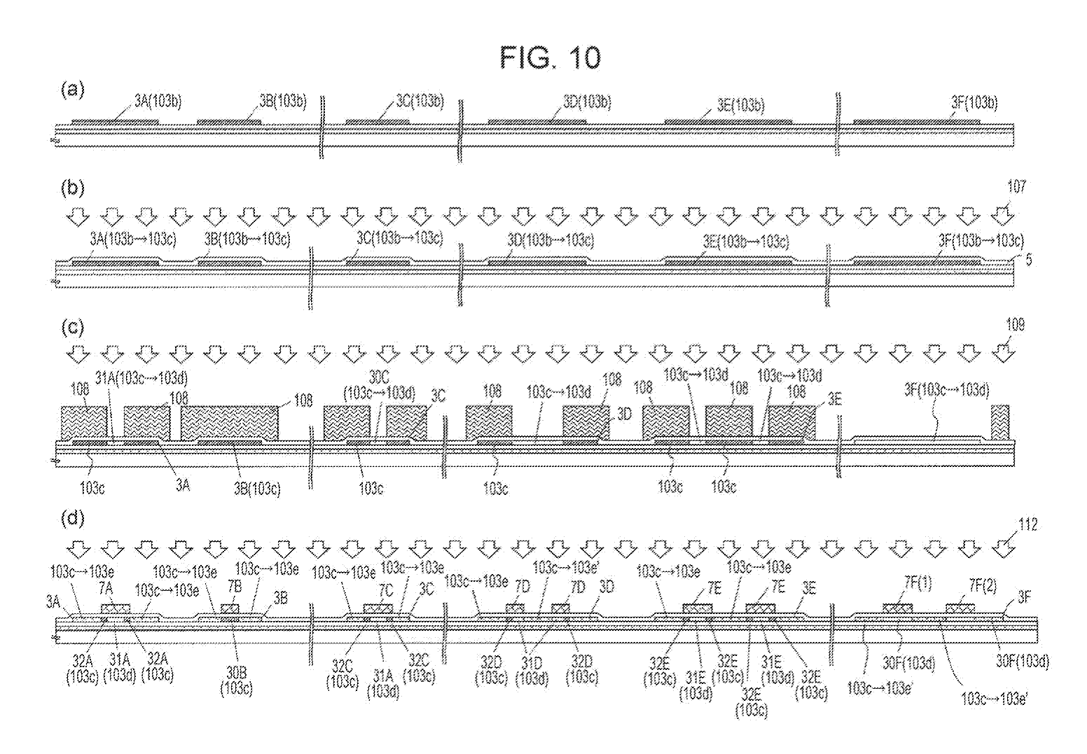

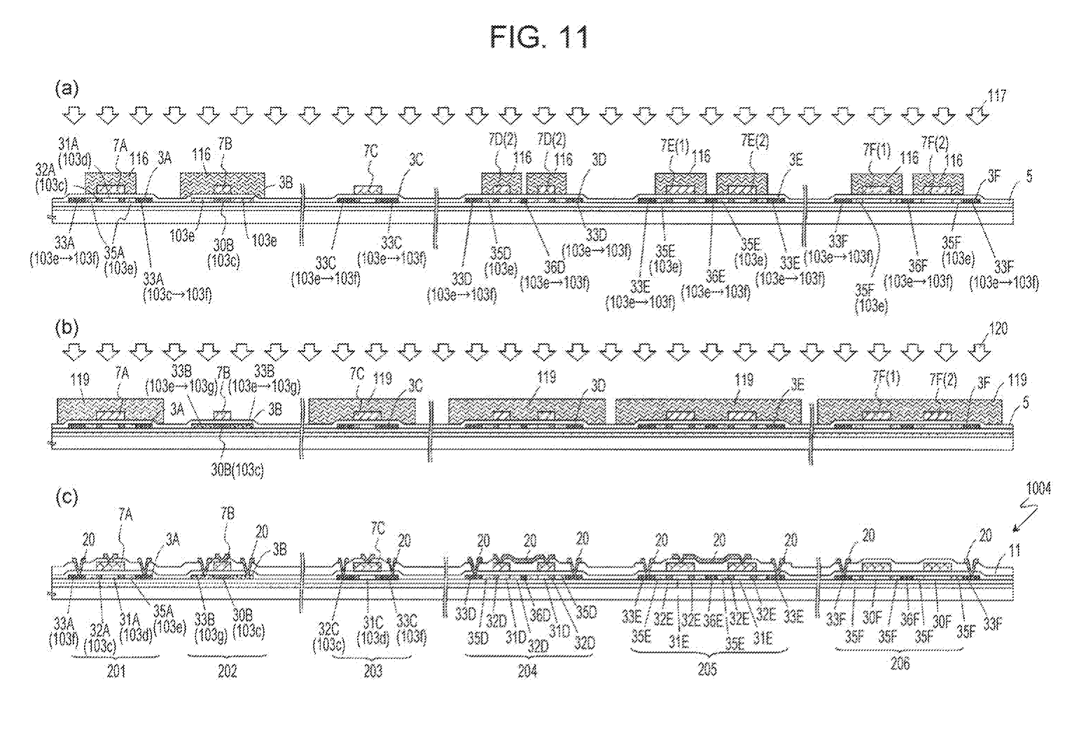

FIGS. 10 and 11 illustrate cross-sections in a process for describing an exemplary method for manufacturing a semiconductor device 1004 according to this embodiment. In these figures, the same or substantially the same components as those in FIGS. 2 to 7 are denoted by the same reference numerals.

In this embodiment, an example of manufacturing the above-described first to fifth TFTs 201 to 205 and a sixth TFT 206 that is an LDD structure TFT without a CDM portion will be described. Note that the semiconductor device 1004 includes the first-conductivity-type CDM-type TFT (any of the first TFT 201 and the third to fifth TFTs 203 to 205), the second-conductivity-type TFT (the second TFT 202) and the sixth TFT 206 on a single substrate. Although a multi-gate (dual-gate, for example)-LDD structure TFT is illustrated as the sixth TFT 206 in this example, the sixth TFT 206 may be a single-gate-LDD structure TFT. The method for manufacturing the first to fifth TFTs 201 to 205 is the same or substantially the same as any of the methods described above with reference to FIGS. 2 to 9, and therefore a description thereof will be omitted as appropriate. Now, an exemplary case in which the first conductivity type is n type and the second conductivity type is p type will be described.

First, as illustrated in FIG. 10(a), by the same or substantially the same method as the method described in the above embodiments, the p-Si film 103b is patterned to form the semiconductor layers 3A to 3E and a semiconductor layer 3F in the form of islands to serve as active regions of the first to sixth TFTs.

Subsequently, channel doping is performed to adjust the threshold voltage of the second TFT to an appropriate value. Specifically, as illustrated in FIG. 10(b), the gate insulating layer 5 is formed to cover the semiconductor layers 3A to 3E. Subsequently, the semiconductor layers 3A to 3E are doped with the p-type impurity 107 to obtain the p-Si region 103c in which the density of the p-type impurity is adjusted.

Subsequently, as illustrated in FIG. 10(c), channel doping is performed to adjust the threshold voltages of the first TFT and the third to sixth TFTs to appropriate values. Specifically, the resist layer 108 is formed on the semiconductor layers 3A to 3E. The resist layer 108 has openings on parts of regions to serve as the channel regions in the semiconductor layers 3A, 3C, 3D, and 3E. Although the resist layer 108 is not formed on the semiconductor layer 3F in this example, the resist layer 108 having an opening on a region to serve as the channel region may also be formed on the semiconductor layer 35.

Subsequently, by using the resist layer 108 as a mask, the semiconductor layers 3A to 3F are further doped with the second-conductivity-type impurity (p-type impurity in this example, boron for example) 109. Thus, the p-Si region 103d further doped with the p-type impurity 109 is formed in the semiconductor layers 3A to 3F. In this example, the semiconductor layer 3F is entirely doped with the p-type impurity 109 to become the p-Si region 103d.

Subsequently, as illustrated in FIG. 10(d), gate electrodes of the first to sixth TFTs are formed on the gate insulating layer 5. As the gate electrodes of the sixth TFT, a gate electrode 7F(1) and a gate electrode 7F(2) are provided to cover the region to serve as the channel region in the semiconductor layer 3F with the gate insulating layer 5 interposed therebetween. The gate electrode 7F(1) and the gate electrode 7F(2) are provided with a gap interposed therebetween.

Subsequently, by using the gate electrodes 7A to 7F as masks, the semiconductor layers 3A to 3F are doped with the first-conductivity-type impurity (n-type impurity in this example) 112. Thus, the n⁻ region is formed in the semiconductor layers 3A to 3F. In this example, the n₋ region 103e′ located between the two CD portions 31D in the semiconductor layer 3D and the n⁻ region 103e′ formed in the semiconductor layer 3F contain the p-type impurity at a higher density than the other n⁻ region 103e for the p-type impurity 109 added in FIG. 8(c).

In the semiconductor layer 3F, regions covered with the gate electrodes 7F(1) and 7F(2) serve as channel regions 30F. The n⁻ region 103e′ is also formed between the channel regions 30F.

Subsequently, as illustrated in FIG. 11(a), the resist layer 116 is formed on the semiconductor layers 3A, 3B, 3D, 3E, and 3F. The resist layer 116 has openings on regions to serve as high-density impurity regions in the semiconductor layers 3A, 3B, 3D, 3E, and 3F. Subsequently, by using the resist layer 116 and the gate electrode 7C as masks, the semiconductor layers 3A, 3B, 3D, 3E, and 3F are doped with the first-conductivity-type impurity (n-type impurity in this example, phosphorus for example) 117. Thus, the n⁺ region 103f is formed. The n⁺ region 103f in the semiconductor layer 3F includes high-density impurity regions 33F and 36F. The high-density impurity region 36F is located between the two channel regions 30F (intra-gate portion). In the n− region 103e in the semiconductor layer 3F, a region not doped with the n-type impurity 117 serves as an LDD region 35F. In this example, the LDD region 35F is formed between each of the channel regions 30F and the high-density impurity region 33F. Note that the LDD region 35F is provided at least one position between a channel region and a high-density impurity region.

Subsequently, as illustrated in FIG. 11(b), the resist layer 119 is formed to cover the semiconductor layers 3A and 3D to 3F, and then the p⁺ region 103g to serve as the high-density impurity region 33B is formed in the semiconductor layer 3B by the method described above with reference to FIG. 4(a).

Subsequently, as illustrated in FIG. 11(c), the interlayer insulating layer 11 is formed to cover the semiconductor layers 3A to 3F. Subsequently, as described above with reference to FIG. 4(b), contact holes are formed in the gate insulating layer 5 and the interlayer insulating layer 11, and then the electrode/wiring 20 is formed. Thus, the semiconductor device 1004 is obtained.

Although the high-density impurity region 36E is formed is the intra-pate portion in the semiconductor layer 3F of the sixth TFT 206 in the illustrated example, an opening does not have to be formed in the resist layer 116 (FIG. 11(a)) at the intra-gate portion, and the high-density impurity region does not have to be formed in the intra-gate portion.

The sixth TFT 206 that is an LDD structure TFT without a CDM portion is suitably applied to, for example, a pixel TFT on an active matrix substrate. Although the pixel TFT is required to have a small off-leakage current, a reduction in the reliability due to hot carriers is not a serious problem. In addition, the CDM portion that might increase capacity is preferably not formed in the pixel TFT.

Thus, according to this embodiment, in addition to the n-type TFT and the p-type TFT that are suitable for circuit TFTs such as driving circuit TFTs, an LDD structure TFT suitable for a pixel TFT can be fabricated without increasing the number of photomasks and the number of manufacturing steps.

Although a crystalline silicon layer has been used as any of the semiconductor layers in the above-described first to fourth embodiments, another semiconductor layer made of SiC, SiGe, or Ge may also be used.

### INDUSTRIAL APPLICABILITY

An embodiment of the present invention is widely applicable to a variety of semiconductor devices including at least two TFTs of different conductivity types. For example, an embodiment of the present invention is applicable to a circuit substrate such as an active matrix substrate; a display device such as a liquid crystal display device, an organic electroluminescent (EL) display device, an inorganic electroluminescent display device, or a MEMS display device; an imaging device such as an image sensor device; and any electronic device such as an image input device, a finger print reading device, or a semiconductor memory.

### REFERENCE SIGNS LIST

1 substrate
3A, 3B semiconductor layer
5 gate insulating layer
7A, 7B gate electrode
8A, 8B source electrode
9A, 9B drain electrode
11 interlayer insulating layer
30A, 30E channel region
31A channel-doped portion (CD portion)
32A channel-doped modulated portion (CDM portion)
33sA, 33sB source region
33dA, 33dB drain region
35A low-density doped region (LDD region)
201, 203-205 first-conductivity-type CDM-type TFT
202 second-conductivity-type TFT
1001, 1002, 1003, 1004 semiconductor device

1. A semiconductor device comprising:
a substrate; and
at least one first thin film transistor supported by the substrate,
wherein the at least one first thin film transistor includes
a first semiconductor layer including a first channel region and a first high-density impurity region containing an impurity of a first conductivity type, the first high-density impurity region including a first source region and a first drain region located on an opposite side of the first source region with the first channel region interposed therebetween,
a gate insulating layer formed on the first semiconductor layer,
a first gate electrode provided on the gate insulating layer to overlap with the first channel region in the first semiconductor layer,
a first source electrode electrically connected to the first source region, and
a first drain electrode electrically connected to the first drain region, and
wherein the first channel region includes a first channel portion and a second channel portion located between the first channel portion and the first high-density impurity region, the first channel portion containing an impurity of a second conductivity type that is different from the first conductivity type at a density higher than that in the second channel portion and the impurity of the first conductivity type at a density substantially equal to that in the second channel portion.

2. The semiconductor device according to claim 1,
wherein the first semiconductor layer further includes a first low-density impurity region that is located between the first high-density impurity region and the first channel region and that contains the impurity of the first conductivity type at a density lower than that in the first high-density impurity region and higher than that in the first channel region, and
wherein the first gate electrode is provided to overlap with the first channel region in the first semiconductor layer with the gate insulating layer interposed therebetween and not to overlap with the first low-density impurity region.

3. The semiconductor device according to claim 2, wherein the first low-density impurity region contains substantially no impurity of the second conductivity type.

4. The semiconductor device according to claim 1, further comprising:
at least one second thin film transistor supported by the substrate, the at least one second thin film transistor being of the second conductivity type,
wherein the at least one second thin film transistor includes a second semiconductor layer including a second channel region and a second high-density impurity region containing the impurity of the second conductivity type, and
wherein the second channel portion in the first semiconductor layer contains the impurity of the second conductivity type at a density substantially equal to the density of the impurity of the second conductivity type in the second channel region in the second semiconductor layer.

5. The semiconductor device according to claim 4,
wherein the first semiconductor layer and the second semiconductor layer are formed of an identical semiconductor film, and
wherein the second channel portion in the first semiconductor layer and the second channel region in the second semiconductor layer contain an identical impurity element of the second conductivity type and have a substantially identical density profile of the impurity element in a thickness direction.

6. The semiconductor device according to claim 1,
wherein the first channel portion and the second channel portion in the first semiconductor layer contain substantially no impurity of the first conductivity type.

7. The semiconductor device according to claim 1,
Wherein, in the first semiconductor layer, the first channel region is adjacent to the first source region and the first drain region.

8. The semiconductor device according to claim 1,
wherein the first semiconductor layer further includes another first channel region and a first-conductivity-type region that is located between the first channel region and the other first channel region and that contains the impurity of the first conductivity type, and
wherein the at least one first thin film transistor further includes another first gate electrode provided to overlap with the other first channel region with the gate insulating layer interposed therebetween.

9. The semiconductor device according to claim 8,
wherein the other first channel region includes another first channel portion and another second channel portion located between the other first channel portion and the first high-density impurity region and between the other first channel portion and the first-conductivity-type region, and
wherein the other first channel portion contains the impurity of the second conductivity type at a density substantially equal to that in the first channel portion, and the other second channel portion contains the impurity of the second conductivity type at a density substantially equal to that in the second channel portion.

10. The semiconductor device according to claim 8,
Wherein the other first channel region includes another first channel portion and another second channel portion located between the other first channel portion and the first high-density impurity region, and the other second channel portion is adjacent to the first-conductivity-type region, and
wherein the other first channel portion contains the impurity of the second conductivity type at a density substantially equal to that in the first channel portion, and the other second channel portion contains the impurity of the second conductivity type at a density substantially equal to that in the second channel portion.

11. The semiconductor device according to claim 1, further comprising:
at least one third thin film transistor,
wherein the at least one third thin film transistor includes
a third semiconductor layer including a third channel region, a third high-density impurity region containing the impurity of the first conductivity type, and a third low-density impurity region that is located between the third high-density impurity region and the third channel region and that contains the impurity of the first conductivity type at a density lower than that in the third high-density impurity region and higher than that in the third channel region, and
a third gate electrode provided on the gate insulating layer to overlap with the third channel region with the gate insulating layer interposed therebetween and not to overlap with the third low-density impurity region, and
wherein the third channel region contains the impurity of the second conductivity type at a density that is substantially equal to the density of the impurity of the second conductivity type in the first channel portion in the first semiconductor layer, and both ends of the third channel region are in contact with the third high-density impurity region or the third low-density impurity region.

12. The semiconductor device according to claim 1,
wherein the at least one first thin film transistor includes a thin film transistor including an LDD region and a thin film transistor without an LDD region.

13. The semiconductor device according to claim 1,
wherein the first conductivity type is n type, and the second conductivity type is p type.

14. The semiconductor device according to claim 1,
wherein the first semiconductor layer contains a crystalline silicon semiconductor.

15. A method for manufacturing a semiconductor device including at least one first thin film transistor and at least one second thin film transistor having a different conductivity type from the first thin film transistor, the method comprising:
(a) a step for forming, on a substrate, a first semiconductor layer in a form of an island to serve as an active region of the first thin film transistor and a second semiconductor layer in a form of an island to serve as an active region of the second thin film transistor;
(b) a step for forming a gate insulating layer covering the first and second semiconductor layers;
(c) a step for forming a first gate electrode to overlap with a region to serve as a channel region in the first semiconductor layer with the gate insulating layer interposed therebetween and forming a second gate electrode to overlap with a region to serve as a channel region in the second semiconductor layer with the gate insulating layer interposed therebetween;
(d) a step for doping a region in the first semiconductor layer not covered with the first gate electrode with an impurity of a first conductivity type to form a first high-density impurity region; and
(e) a step for doping a region in the second semiconductor layer not covered with the second gate electrode with an impurity of a second conductivity type to form a second high-density impurity region, further comprising:
between the step (a) and the step (c), a channel doping step (f1) for doping a part of a region to serve as the channel region in the first semiconductor layer with the impurity of the second conductivity type to form a first channel portion in the first semiconductor layer,
wherein, in the region to serve as the channel region in the first semiconductor layer, a region not doped with the impurity of the second conductivity type in the step (f1) becomes a second channel portion, and
wherein the second channel portion in the first semiconductor layer contains the impurity at a density that is substantially equal to a density of the impurity in the channel region in the second semiconductor layer.

16. The method for manufacturing a semiconductor device according to claim 15, further comprising:
between the step and the step (c), a step (f2) for doping the region to serve as the channel region in the second semiconductor layer and the region to serve as the channel region in the first semiconductor layer with the impurity of the second conductivity type,
wherein, in the region to serve as the channel region in the first semiconductor layer, a region doped with the impurity of the second type in both the step (f1) and the step (f2) serves as the first channel portion, and a region not doped with the impurity of the second conductivity type in the step (f1) but doped with the impurity of the second conductivity type in the step (f2) becomes the second channel portion.

17. The method for manufacturing a semiconductor device according to claim 15,
wherein the step (d) is a step tor doping a region in the first semiconductor layer not covered with the first gate electrode with the impurity of the first conductivity type to form the first high-density impurity region and a first low-density impurity region that is located on a channel side of the first high-density impurity region and that contains the impurity of the first conductivity type at a density lower than a density in the first high-density impurity region.
